(19) United States
(12) Patent Application Publication
(10) Pub. No.: US 2026/0020183 A1
(43) Pub. Date: Jan. 15, 2026

(54) IMMERSION COOLING SYSTEM

(71) Applicant: Quanta Computer Inc., Taoyuan City (TW)

(72) Inventors: Yi-Chieh CHEN, Taoyuan City (TW); Yueh-Chang WU, Taoyuan City (TW); Te-Chuan WANG, Taoyuan City (TW); Tzu-Hsuan HSU, Taoyuan City (TW); Tzu-Chun YANG, Taoyuan City (TW)

(21) Appl. No.: 18/767,196

(22) Filed: Jul. 9, 2024

(51) Int. Cl. H05K 7/20; G06F 1/20

(52) U.S. Cl. CPC H05K 7/20236; H05K 7/20272; H05K 7/20281; G06F 1/20

(57) ABSTRACT

An immersion cooling system includes a tank configured to hold liquid coolant and one or more instances of computer equipment submerged within the liquid coolant The tank is configured to have a first tank inlet, a second tank inlet, and a tank outlet. The immersion cooling system further includes a pump configured to have a pump inlet and a pump outlet coupled to the first tank inlet. The immersion cooling system further includes a coolant distribution unit (CDU) configured to have a distribution inlet coupled to the tank outlet and a distribution outlet that is coupled to the second tank inlet and the pump inlet.

### FIELD OF THE INVENTION

The present invention relates generally to an immersion cooling system, and more specifically, to an immersion cooling system that includes a cooling loop that distributes liquid coolant directly to heat generating components within a computer housing.

### BACKGROUND OF THE INVENTION

Current computing systems have high-performance computing requirements with multiple energy-intensive, heat-generating processers, such as central processing units (CPUs) and graphics processing units (GPUs). The maximum power consumption of a central processing unit (CPU) can be above 350 watts (W), and the maximum power consumption of a graphics processor unit (GPU) can be above 700 W. Traditional air cooling is inadequate to properly cool the newer generation of processors. Liquid cooling systems, such as immersion cooling and direct-to-chip cooling, have been applied to dissipate the heat generated by processors with these power consumption levels. However, known liquid cooling systems have performance limitations and/or undesirable features. For example, immersion cooling utilizes a tank of dielectric liquid that is circulated to cool one or more computers that are entirely immersed in the dielectric liquid to cool the entire computer. However, immersion cooling is limited in cooling capability to about 500 W. Direct-to-chip cooling in the form of a cold plate, which can provide a higher level of cooling capability, is applied directly to a heat generating component within a computer and only cools the component to which it is attached. Direct-to-chip cooling also utilizes water-based liquid that can leak onto the component which can result in short circuits and thus disrupt operation of the computer. A need exists for a cooling system that has a higher cooling capability that can reliably, safely, and economically cool large heat loads generated by one or more computers, while also being easy to implement and easily scalable to cool a single computer or a room full of computer systems simultaneously.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and cach claim.

According to certain aspects of the present disclosure, an immersion cooling system comprises a tank configured to hold liquid coolant and one or more instances of computer equipment submerged within the liquid coolant. The tank is configured to have a first tank inlet, a second tank inlet, and a tank outlet. The immersion cooling system further comprises a pump having a pump inlet and a pump outlet coupled to the first tank inlet. The immersion cooling system further comprises a coolant distribution unit (CDU) having a distribution inlet coupled to the tank outlet, and a distribution outlet coupled to both the second tank inlet and the pump inlet.

According to certain aspects of the present disclosure, the one or more instances of computer equipment are sufficiently separated from each other to be each surrounded by the liquid coolant.

According to certain aspects of the present disclosure, the distribution outlet directs a first portion of the liquid coolant to the second tank inlet, and a second portion of the coolant to the pump inlet.

According to certain aspects of the present disclosure, the immersion cooling system further comprises one or more pipes that extend into a housing of each of the one or more instances of the computer equipment. Each of the one or more pipes is coupled to the first tank inlet. Each of the one or more pipes directly distributes the liquid coolant to a component within a respective housing.

According to certain aspects of the present disclosure, each of the one or more pipes directly distributes the liquid coolant to a heat sink attached to the respective component within the respective housing.

According to certain aspects of the present disclosure, the immersion cooling system further comprises a nozzle coupled to an outlet of each of the one or more pipes. The nozzle has a width along which the liquid coolant is evenly and directly distributed to the heat sink.

According to certain aspects of the present disclosure, the immersion cooling system further comprises a first manifold coupling the first tank inlet to each of the one or more pipes.

According to certain aspects of the present disclosure, the first manifold is disposed across a top of the tank.

According to certain aspects of the present disclosure, the immersion cooling system further comprises comprising a second manifold coupled to the second tank inlet. The second manifold has one or more apertures for distributing the liquid coolant into the tank.

According to certain aspects of the present disclosure, the liquid coolant is a dielectric liquid coolant.

According to certain aspects of the present disclosure, an immersion cooling system comprises a first cooling loop comprising a coolant distribution unit (CDU) having a distribution inlet and a distribution outlet. The first cooling loop further comprises a tank configured to hold a liquid coolant and one or more instances of computer equipment submerged within the liquid coolant. The tank is configured to have a first tank inlet in fluid communication with the distribution outlet and a tank outlet in fluid communication with the distribution inlet. The immersion cooling system further comprises a second cooling loop comprising the CDU and the tank configured to have the tank outlet in fluid communication with the distribution inlet. The second cooling loop further comprises a pump having a pump inlet in fluid communication with the distribution outlet and a pump outlet in fluid communication with the second tank inlet.

According to certain aspects of the present disclosure, the one or more instances of computer equipment are sufficiently separated from each other to be each surrounded by the liquid coolant.

According to certain aspects of the present disclosure, the distribution outlet directs a first portion of the liquid coolant to the first tank inlet, and a second portion of the liquid coolant to the pump inlet.

According to certain aspects of the present disclosure, the immersion cooling system further comprises one or more pipes that extend into a housing of each of the one or more instances of the computer equipment. Each of the one or more pipes is coupled to the second tank inlet. Each of the one or more pipes directly distributes the liquid coolant to a component within a respective housing.

According to certain aspects of the present disclosure, each of the one or more pipes directly distributes the liquid coolant to a heat sink attached to the respective component within the respective housing.

According to certain aspects of the present disclosure, the immersion cooling system further comprises a nozzle coupled to an outlet of each of the one or more pipes. The nozzle has a width along which the liquid coolant is evenly and directly distributed to the heat sink.

According to certain aspects of the present disclosure, the immersion cooling system further comprises a first manifold coupling the second tank inlet to each of the one or more pipes.

According to certain aspects of the present disclosure, the first manifold is disposed across a top of the tank.

According to certain aspects of the present disclosure, the immersion cooling system further comprises a second manifold coupled to the first tank inlet. The second manifold has one or more apertures for distributing the liquid coolant into the tank.

According to certain aspects of the present disclosure, the liquid coolant is a dielectric liquid coolant.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective view showing a known direct-to-chip cooling system.

FIG. 2 is a schematic view of a known immersion cooling system.

FIG. 3 is a schematic view of another known immersion cooling system.

FIG. 4 is a schematic view of a first immersion cooling system, according to certain aspects of the present disclosure.

FIG. 5 is a schematic view of a second immersion cooling system, according to certain aspects of the present disclosure.

FIG. 6 is a schematic view of a third immersion cooling system, according to certain aspects of the present disclosure.

FIG. 7 is a schematic view of a fourth immersion cooling system, according to certain aspects of the present disclosure.

FIG. 8 is a schematic view of a fifth immersion cooling system, according to certain aspects of the present disclosure.

### DETAILED DESCRIPTION

The current invention is an immersion cooling system including two connected cooling loops. A first cooling loop delivers liquid coolant into a tank in which computers within housings are immersed. A second cooling loop distributes the liquid coolant directly to heat generating components of the computers within their housings. The immersion cooling system uses a single liquid coolant in both cooling loops.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or clement(s); or as otherwise described herein.

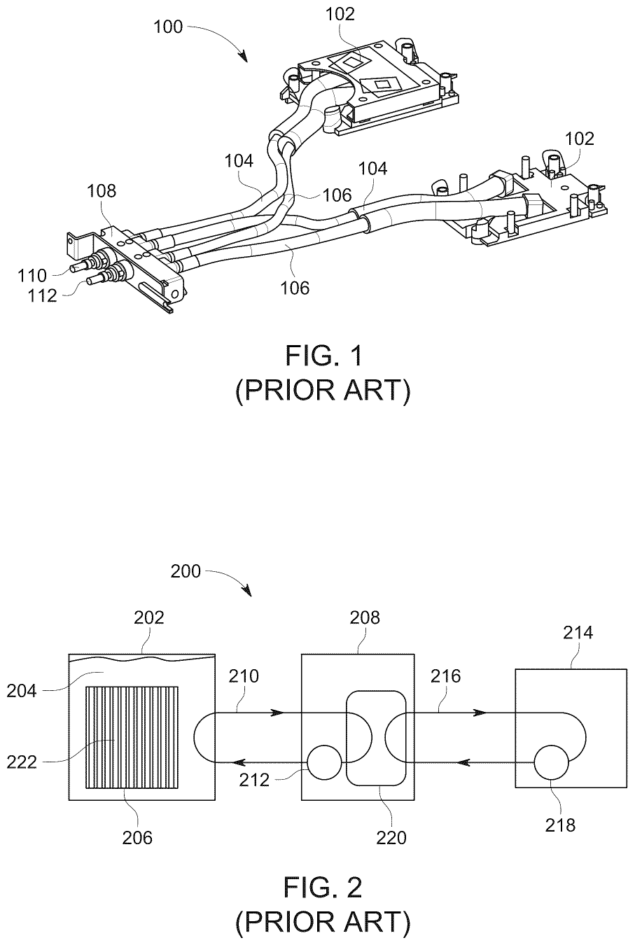

Known liquid cooling systems for computers include direct-to-chip cooling and immersion cooling. Referring to FIG. 1, an example of a known direct-to-chip cooling system 100 is illustrated. The direct-to-chip cooling system 100 includes at least one cold plate 102 (two are shown) that each connect via a plate input line 104 and a plate output line 106 to a manifold 108 that combines the individual plate input lines 104 and plate output lines 106 into a single input line 110 and output line 112, respectively. In use, each of the cold plates 102 would be placed into thermal contact with a component to be cooled, for example, a CPU or GPU, and coolant, for example water, would be circulated through the cold plates through the input line 110 and the output line 112. Each of the cold plates 102 of such a direct-to-chip cooling system 100 is capable of dissipating a heat load of more than 1000 W.

Referring to FIG. 2, an example of a known immersion cooling system 200 is illustrated. The immersion cooling system 200 includes a tank 202 containing a liquid coolant 204 that is typically a dielectric coolant. In use, computer equipment 206, including the entire piece of equipment in its housing, is immersed in the liquid coolant 204. A coolant distribution unit (CDU) 208 circulates the liquid coolant 204 through the tank 202 in a first coolant loop 210, for example, via a pump 212. Another coolant, for example, from a chiller 214 is pumped through a second coolant loop 216, for example, by a second pump 218. The first coolant loop 210 and the second coolant loop 216 are brought into thermal contact in a heat exchanger 220 within the CDU 208 to transfer dissipated heat within the liquid coolant 204 in the first coolant loop 210 to the other coolant in the second coolant loop 216. A heat sink 222, represented by the vertical lines in FIG. 2, could also be attached to each piece of computer equipment 206 immersed in the liquid coolant 204 of the tank 202. Such an immersion cooling system 200 is capable of dissipating a heat load of about 500 W.

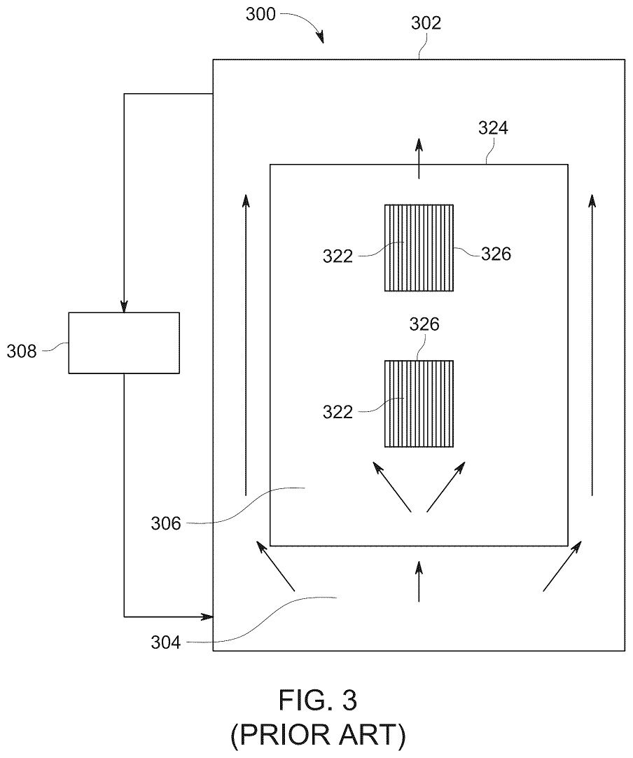

Referring to FIG. 3, in an embodiment of another known immersion cooling system 300, a CDU 308 circulates liquid coolant 304 (as illustrated by the generally vertically oriented arrows) through a tank 302. A computer 306 within its housing 324 is immersed in the liquid coolant 304. In this embodiment, a heat sink 322, represented by the vertical lines in FIG. 3, has been attached, for example, to each of two heat generating components 326 within the computer housing 324. However, because the computer housing 324 surrounds the heat generating components 326, the computer housing 324 presents a physical barrier to flow through the housing. The resulting flow field of the liquid coolant 304 through the tank 302 provides an inadequate flowrate of the coolant 304 through the computer housing 324 and over the heat generating components 326.

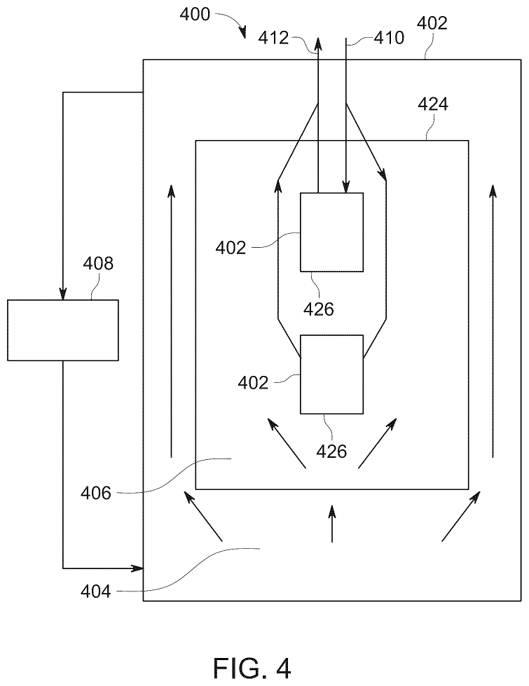

Referring to FIG. 4, concepts from the direct-to-chip cooling system 100 shown in FIG. 1 have been introduced into in an embodiment of an immersion cooling system 400. In this embodiment, a CDU 408 circulates liquid coolant 404 through a tank 402. A computer 406 within a housing 424 is immersed in the liquid coolant 404. Heat generating components 426 each have a cold plate 402 disposed in thermal contact with the heat generating components 426. Coolant, for example, water is circulated through each of the cold plates 402 via input line 410 and output line 412.

In the immersion cooling system 400, the heat generating components 426 are cooled by the cold plates 402 while other components of the computer 406 within the housing 424 are cooled through immersion cooling. While this arrangement can provide an improvement in cooling capacity, the cold plates 402 utilize water as coolant and the immersion tank utilizes the liquid coolant 404, which cannot be water.

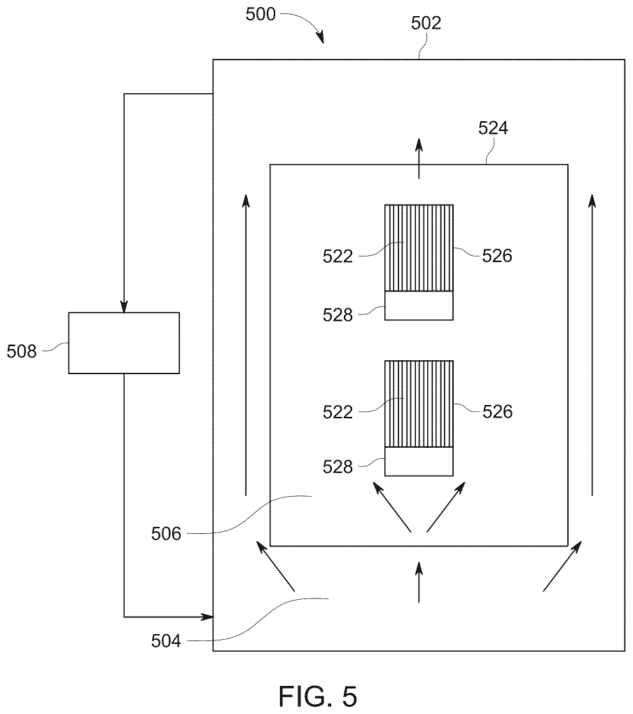

Referring to FIG. 5, an immersion cooling system 500 is similar to the immersion cooling system 300 described in FIG. 3 above. A CDU 508 circulates liquid coolant 504 through a tank 502. A computer 506 within its housing 524 is immersed in the liquid coolant 504. Heat sinks 522, represented by the vertical lines in FIG. 5, have been attached, for example, to each of two heat generating components 526 within the computer housing 524. Each of the heat sinks 522 has an attached fan 528 configured to drive liquid coolant 504 into the heat sink 522. This embodiment provides an adequate flowrate of the liquid coolant 504 to cool the heat generating components 522.

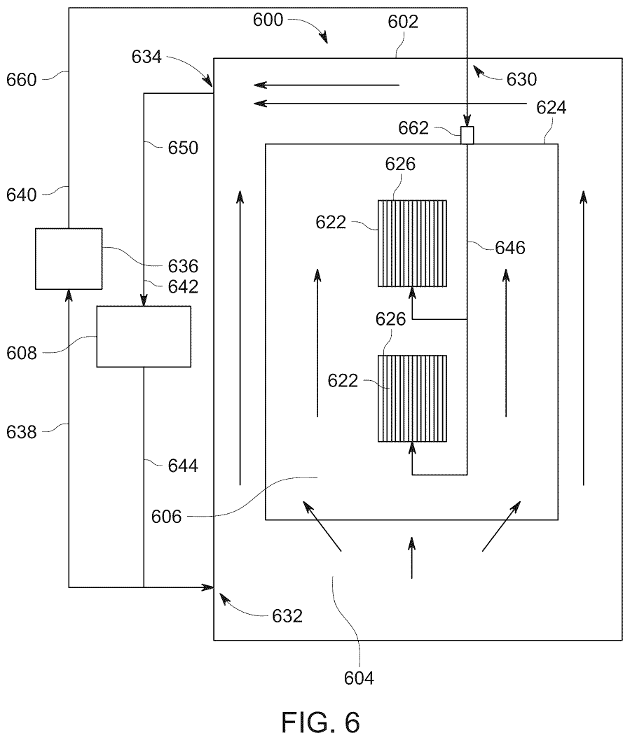

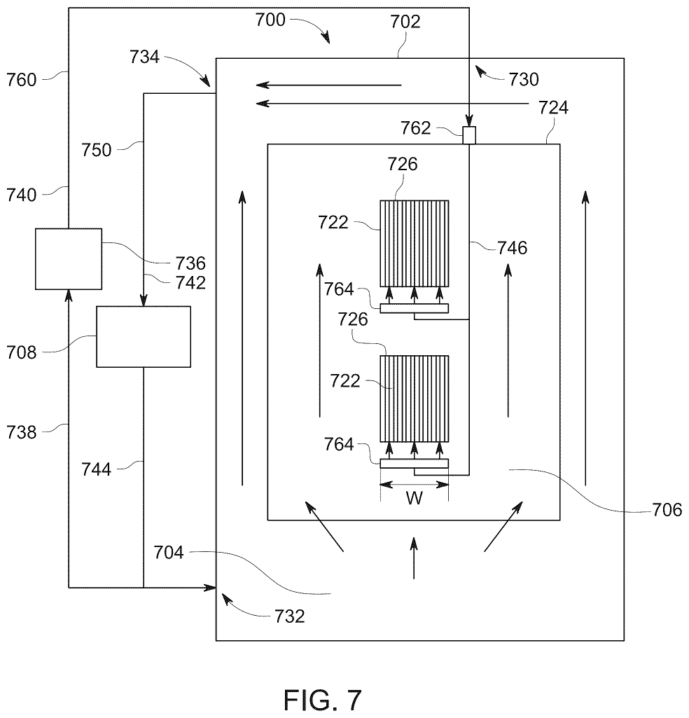

Referring to FIG. 6, an immersion cooling system 600 comprises a tank 602 configured to hold liquid coolant 604 and one or more instances of computer equipment 606. Thus, each instance of computer equipment 606 is contained within a housing 624 that are each submerged within the liquid coolant 604 in the tank 602. The tank 602 is configured to have a first tank inlet 630, a second tank inlet 632, and a tank outlet 634. The immersion cooling system 600 further comprises a pump 636 configured to have a pump inlet 638 and a pump outlet 640 coupled to the first tank inlet 630. The immersion cooling system 600 further comprises a CDU 608 configured to have a distribution inlet 642 coupled to the tank outlet 634 and a distribution outlet 644 that is coupled to the second tank inlet 632 and the pump inlet 638. In an embodiment, the distribution outlet 644 is configured so that a first portion of the liquid coolant 604 is directed to the second tank inlet 632 and a second portion of the coolant is directed to the pump 636. In an embodiment the relative amounts of the liquid coolant 604 directed to the second tank inlet 632 and the pump inlet 638 can be dependent upon the heat load of the one or more instances of computer equipment 606.

The immersion cooling system 600 further comprises one or more pipes 646 configured to extend into the housing 624 of each of the one or more instances of the computer equipment 606. The one or more pipes 646 are coupled to the first tank inlet 630 and configured to directly distribute the liquid coolant 604 to a heat generating component 626 within the housing 624. In an embodiment, a pipe connector 662 disposed on the housing 624 connects the one or more pipes 646 to the first tank inlet 630. In an embodiment, a heat sink 622 is attached to each of the heat generating components 626 within the housing 624, and each of the one or more pipes 646 is further configured to directly distribute the liquid coolant 604 to the heat sink 622 attached to each of the heat generating components 626 within the housing 624.

Still referring to FIG. 6, the immersion cooling system 600 can be described in the context of cooling loops. For example, the immersion cooling system 600 comprises a first cooling loop 650 and a second cooling loop 660. The first cooling loop 650 comprises the CDU 608, which is configured to have the distribution inlet 642 and the distribution outlet 644. The tank 602 is configured to have the second tank inlet 632 in fluid communication with the distribution outlet 644, and the tank outlet 634 in fluid communication with the distribution inlet 642.

The second cooling loop 660 comprises the CDU 608. The tank 602 is configured to have the tank outlet 634 in fluid communication with the distribution inlet 642, and the pump 636 is configured to have a pump inlet 638 in fluid communication with the distribution outlet 644 and a pump outlet 640 in fluid communication with the first tank inlet 630. The second cooling loop further comprises the one or more pipes 646 configured to extend into the housing 624 of each of the one or more instances of the computer equipment 606. The one or more pipes 646 are coupled to the first tank inlet 630, and configured to directly distribute the liquid coolant 604 to the heat sink 622 of the heat generating component 626 within the housing 624. The direct distribution of the liquid coolant 604 to the heat sink 622 provides a more efficient forced convective transfer of heat from the heat sink 622 to the liquid coolant 604.

Each of the first and second cooling loops 650, 660 is open to the inside of the tank 602. Liquid coolant 604 from the CDU 608 is introduced into the tank 602 at the second tank inlet 632 and flows through the tank 602 to the tank outlet 634. Liquid coolant 604 from the pump 636 exits the one or more pipes 646; flows through the housing 624 into the tank 602; and also flows to the tank outlet 634. Thus, only one type of liquid coolant 604, such as a dielectric liquid, is required.

A pipe connector 662 disposed on the housing 624 connects the one or more pipes 646 to the first tank inlet 630. The one or more pipes 646 directly distribute cold liquid coolant 604 forced by the pump 636 to each heat sink 622. The one or more pipes 646 directing the liquid coolant 604 into the housing 624, and the pump 636 providing a driving force, significantly improves the flowrate of the liquid coolant 604 over the heat sinks 622.

Although the flowrate of the liquid coolant 604 over each heat sink 622 is improved by the pump 636 and the one or more pipes 646, the liquid coolant 604 exiting from the one or more pipes 646 can impinge non-uniformly on only a portion of each heat sink 622. Referring to FIG. 7, an immersion cooling system 700 adds nozzles 764 to the immersion cooling system 600 (in FIG. 6). Each nozzle 764 is disposed at the outlet of the one or more pipes 746 to provide a more uniform flow of the liquid coolant 704 over each heat sink 722. Therefore, the immersion cooling system 700 comprises a tank 702 configured to hold liquid coolant 704 and one or more instances of computer equipment 706, for example with each instance of computer equipment 706 contained within a housing 724, submerged within the liquid coolant 704. The tank 702 is configured to have a first tank inlet 730, a second tank inlet 732, and a tank outlet 734. The immersion cooling system 700 further comprises a pump 736 configured to have a pump inlet 738 and a pump outlet 740 coupled to the first tank inlet 730. The immersion cooling system 700 further comprises a CDU 708 configured to have a distribution inlet 742 coupled to the tank outlet 734 and a distribution outlet 744 that is coupled to the second tank inlet 732 and the pump inlet 738. In an embodiment, the distribution outlet 744 is configured so that a first portion of the liquid coolant 704 is directed to the second tank inlet 732 and a second portion of the coolant is directed to the pump 736. In an embodiment the relative amounts of the liquid coolant 704 directed to the second tank inlet 732 and the pump 736 can be dependent upon the heat load of the one or more instances of computer equipment 706.

The immersion cooling system 700 further comprises one or more pipes 746 configured to extend into the housing 724 of each of the one or more instances of the computer equipment 706. The one or more pipes 746 are coupled to the first tank inlet 730 and configured to directly distribute the liquid coolant 704 to a heat generating component 726 within the housing 724. In an embodiment, a pipe connector 762 disposed on the housing 724 connects the one or more pipes 746 to the first tank inlet 730. In an embodiment, a heat sink 722 is attached to each of the heat generating components 726 within the housing 724, and each of the one or more pipes 746 is further configured to directly distribute the liquid coolant 704 to the heat sink 722 attached to each of the heat generating components 726 within the housing 724.

As noted, the immersion cooling system 700 further includes a nozzle 764 coupled to an outlet of each of the one or more pipes 746. In an embodiment, the nozzle 764 has a width, W, sized to be about the same width as the heat sink 722. Each nozzle 764 is configured to output the liquid coolant 704 in an even distribution along the width W. Each nozzle 764 is configured to directly distribute the liquid coolant 704 to the heat sink 722 evenly along the width W.

Still referring to FIG. 7, and similar to the immersion cooling system 600 (in FIG. 6), the immersion cooling system 700 can be described in the context of cooling loops. For example, in an embodiment, the immersion cooling system 700 comprises a first cooling loop 750 and a second cooling loop 760. The first cooling loop 750 comprises the CDU 708 configured to have the distribution inlet 742 and the distribution outlet 744, and the tank 702 configured to have the second tank inlet 732 in fluid communication with the distribution outlet 744 and the tank outlet 734 in fluid communication with the distribution inlet 742.

The second cooling loop 760 comprises the CDU 708, the tank 702 configured to have the tank outlet 734 in fluid communication with the distribution inlet 742, and the pump 736 configured to have a pump inlet 738 in fluid communication with the distribution outlet 744 and a pump outlet 740 in fluid communication with the first tank inlet 730. In an embodiment, the second cooling loop further comprises the one or more pipes 746 configured to extend into the housing 724 of each of the one or more instances of the computer equipment 706. The one or more pipes 746 are coupled to the first tank inlet 730 and configured to directly distribute the liquid coolant 704 to the heat generating component 726 within the housing 724.

Each of the first and second cooling loops 750, 760 is open to the inside of the tank 702. Liquid coolant 704 from the CDU 708 is introduced into the tank 702 at the second tank inlet 732 and flows through the tank 702 to the tank outlet 734. Liquid coolant 704 from the pump 736 exits the one or more pipes 746, flows through the housing 724 into the tank 702 and also flows to the tank outlet 734. Thus, only one type of liquid coolant 704 is required. In an embodiment, a pipe connector 762 disposed on the housing 724 connects the one or more pipes 746 to the first tank inlet 730. The second cooling loop further includes the nozzle 764 coupled to the end of each of the one or more pipes 746. Test results have shown that the immersion cooling system 700 provides a reduction in temperature of 10.5° C. for each heat generating component 726 (for example, a CPU) compared to the immersion cooling system 300 described with regard to FIG. 3.

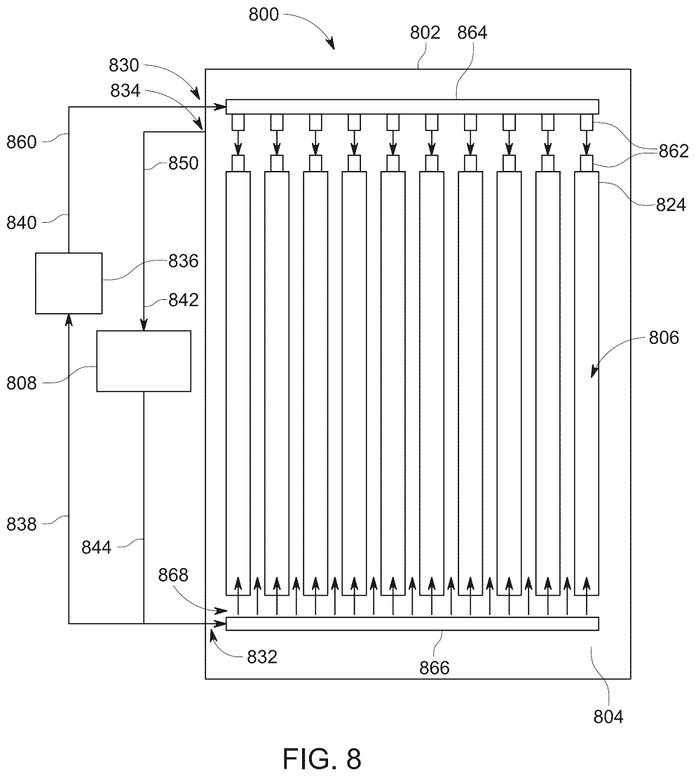

Referring to FIG. 8, an immersion cooling system 800 can support two or more instances of the computer equipment 806, each disposed within a housing 824. The immersion cooling system 800 comprises a tank 802 configured to hold liquid coolant 804 and the two or more instances of computer equipment 806, for example with each instance of computer equipment 806 contained within a housing 824, the housing 824 submerged within the liquid coolant 804. The tank 802 is configured to hold the two or more instances of computer equipment 806, each within the housing 824, sufficiently separated to be surrounded by the liquid coolant 804.

The tank 802 is configured to have a first tank inlet 830, a second tank inlet 832, and a tank outlet 834. The immersion cooling system 800 further comprises a pump 836 configured to have a pump inlet 838 and a pump outlet 840 coupled to the first tank inlet 830. The immersion cooling system 800 further comprises a CDU 808 configured to have a distribution inlet 842 coupled to the tank outlet 834 and a distribution outlet 844 that is coupled to the second tank inlet 832 and the pump inlet 838. In an embodiment, the distribution outlet 844 is configured so that a first portion of the liquid coolant 804 is directed to the second tank inlet 832 and a second portion of the coolant is directed to the pump 836. In an embodiment the relative amounts of the liquid coolant 804 directed to the second tank inlet 832 and the pump 836 can be dependent upon the heat load of the one or more instances of computer equipment 806.

Although internal features of each housing 824 are not shown in FIG. 8 for clarity, the immersion cooling system 800 further comprises the one or more pipes 746 (in FIG. 7), configured to extend into the housing 824 of each of the two or more instances of the computer equipment 806. In the immersion cooling system 800, the one or more pipes 746 are coupled to a first manifold 864 that couples the first tank inlet 830 to each instance of the one or more pipes 746. The manifold 864 is disposed across a top of the tank 802. The one or more pipes 746 are configured to directly distribute the liquid coolant 804 to a heat generating component 726 (see FIG. 7) within each housing 824. In an embodiment, a pipe connector 862 has a first end disposed on each housing 824 and connected to the one or more pipes 746 in each housing 824. The pipe connector 862 has a second end disposed on the manifold 864 allowing the flow of liquid coolant 804 out of the manifold 864 and into the one or more pipes 746. In an embodiment, a heat sink 722 (see FIG. 7) is attached to each of the heat generating components 726 within each housing 824, and each of the one or more pipes 746 is further configured to directly distribute the liquid coolant 804 to the heat sink 722 attached to each of the heat generating components 726 within each housing 824.

A nozzle 764 (see FIG. 7) is coupled to an outlet of each of the one or more pipes 746. In an embodiment, the nozzle 764 has a width, W (see FIG. 7), sized to be about the same width as the heat sink 722. Each nozzle 764 is configured to output the liquid coolant 804 in an even distribution along the width W. Each nozzle 764 is configured to directly distribute the liquid coolant 804 to the heat sink 722 evenly along the width W. In an embodiment, the immersion cooling system 800 further comprises a second manifold 866 coupled to the second tank inlet 832, the second manifold 866 having one or more apertures 868 for distributing the liquid coolant 804 into the tank 802.

Still referring to FIG. 8, and similar to the immersion cooling system 700 in FIG. 7, the immersion cooling system 800 can be described in the context of cooling loops. For example, in an embodiment, the immersion cooling system 800 comprises a first cooling loop 850 and a second cooling loop 860. The first cooling loop 850 includes all of the structure described hereinabove for the first cooling loop 750 (in FIG, 7). In addition, the first cooling loop 850 includes the second manifold 866. The second cooling loop 860 includes all of the structure described hereinabove for the second cooling loop 760 (in FIG. 7). In addition, the second cooling loop 860 includes the manifold 864 and the pipe connectors 862.

Each of the first and second cooling loops 850, 860 is open to the inside of the tank 802. Liquid coolant 804 from the CDU 808 is introduced into the tank 802 at the second tank inlet 832 and flows through the tank 802 to the tank outlet 834. Liquid coolant 804 from the pump 836 exits the one or more pipes 746, flows through each housing 824 into the tank 802 and also flows to the tank outlet 834. For any of the embodiments of the liquid cooling system 600, 700, 800, only one liquid coolant 604, 704, 804 is required. In an embodiment, the liquid coolant 604, 704, 804 is a dielectric liquid coolant.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. An immersion cooling system comprising:
a tank configured to hold a liquid coolant and one or more instances of computer equipment submerged within the liquid coolant, the tank being configured to have a first tank inlet, a second tank inlet, and a tank outlet;
a pump having a pump inlet and a pump outlet, the pump outlet being coupled to the first tank inlet; and
a coolant distribution unit (CDU) having a distribution inlet coupled to the tank outlet and a distribution outlet coupled to both the second tank inlet and the pump inlet.

2. The immersion cooling system of claim 1, wherein the one or more instances of computer equipment are sufficiently separated from each other to be each surrounded by the liquid coolant.

3. The immersion cooling system of claim 1, wherein the distribution outlet directs a first portion of the liquid coolant to the second tank inlet and a second portion of the coolant to the pump inlet.

4. The immersion cooling system of claim 1, further comprising one or more pipes that extend into a housing of each of the one or more instances of the computer equipment, each of the one or more pipes being coupled to the first tank inlet, each of the one or more pipes directly distributing the liquid coolant to a component within a respective housing.

5. The immersion cooling system of claim 4, wherein each of the one or more pipes directly distributes the liquid coolant to a heat sink attached to the respective component within the respective housing.

6. The immersion cooling system of claim 5, further comprising a nozzle coupled to an outlet of each of the one or more pipes, the nozzle having a width along which the liquid coolant is evenly and directly distributed to the heat sink.

7. The immersion cooling system of claim 4, further comprising a first manifold coupling the first tank inlet to each of the one or more pipes.

8. The immersion cooling system of claim 7, wherein the first manifold is disposed across a top of the tank.

9. The immersion cooling system of claim 7, further comprising a second manifold coupled to the second tank inlet, the second manifold having one or more apertures for distributing the liquid coolant into the tank.

10. The immersion cooling system of claim 1, wherein the liquid coolant is a dielectric liquid coolant.

11. An immersion cooling system, comprising:
a first cooling loop, comprising:
a coolant distribution unit (CDU) having a distribution inlet and a distribution outlet; and
a tank configured to hold a liquid coolant and one or more instances of computer equipment submerged within the liquid coolant, the tank being configured to have a first tank inlet in fluid communication with the distribution outlet and a tank outlet in fluid communication with the distribution inlet; and
a second cooling loop, comprising:
the CDU;
the tank configured to have the tank outlet in fluid communication with the distribution inlet; and
a pump having a pump inlet in fluid communication with the distribution outlet and a pump outlet in fluid communication with the second tank inlet.

12. The immersion cooling system of claim 11, wherein the one or more instances of computer equipment are sufficiently separated from each other to be each surrounded by the liquid coolant.

13. The immersion cooling system of claim 11, wherein the distribution outlet directs a first portion of the liquid coolant to the first tank inlet and a second portion of the liquid coolant to the pump inlet.

14. The immersion cooling system of claim 11, further comprising one or more pipes that extend into a housing of each of the one or more instances of the computer equipment, each of the one or more pipes being coupled to the second tank inlet, each of the one or more pipes directly distributing the liquid coolant to a component within a respective housing.

15. The immersion cooling system of claim 14, wherein each of the one or more pipes directly distributes the liquid coolant to a heat sink attached to the respective component within the respective housing.

16. The immersion cooling system of claim 15, further comprising a nozzle coupled to an outlet of each of the one or more pipes, the nozzle having a width along which the liquid coolant is evenly and directly distributed to the heat sink.

17. The immersion cooling system of claim 14, further comprising a first manifold coupling the second tank inlet to each of the one or more pipes.

18. The immersion cooling system of claim 17, wherein the first manifold is disposed across a top of the tank.

19. The immersion cooling system of claim 17, further comprising a second manifold coupled to the first tank inlet, the second manifold having one or more apertures for distributing the liquid coolant into the tank.

20. The immersion cooling system of claim 11. wherein the liquid coolant is a dielectric liquid coolant.
